(19) United States
(12) Patent Application Publication
(10) Pub. No.: US 2022/0399339 A1
(43) Pub. Date: Dec. 15, 2022

(54) TRANSISTOR STRUCTURE AND MEMORY STRUCTURE

(71) Applicant: Powerchip Semiconductor Manufacturing Corporation, Hsinchu (TW)

(72) Inventors: Chun-Sheng Chen, Hsinchu City (TW); Chiu-Tsung Huang, Hsinchu City (TW)

(73) Assignee: Powerchip Semiconductor Manufacturing Corporation, Hsinchu (TW)

(21) Appl. No.: 17/378,786

(22) Filed: Jul. 19, 2021

(30) Foreign Application Priority Data
Jun. 15, 2021 (TW) 110121650

(51) Int. Cl. H01L 27/108; H01L 23/522; H01L 23/528; H01L 29/10

(52) U.S. Cl. CPC H01L 27/10805; H01L 23/5226; H01L 23/5283; H01L 29/1025

(57) ABSTRACT

A transistor structure including a first doped layer, a second doped layer, a channel layer, a gate, and a dielectric structure is provided. The second doped layer is located on the first doped layer. The channel layer is located between the first doped layer and the second doped layer. The gate penetrates through the second doped layer and the channel layer. The second doped layer and the channel layer respectively surround the gate. The dielectric structure is located between the gate and the second doped layer and located between the gate and the channel layer.

### CROSS-REFERENCE TO RELATED APPLICATION

This application claims the priority benefit of Taiwan application serial no. 110121650, filed on Jun. 15, 2021. The entirety of the above-mentioned patent application is hereby incorporated by reference herein and made a part of this specification.

### BACKGROUND OF THE INVENTION

### Field of the Invention

The invention relates to a semiconductor structure, and particularly relates to a transistor structure and a memory structure.

### Description of Related Art

With the advancement of semiconductor technology, the semiconductor industry continues to shrink the size of the semiconductor device (e.g., transistor) in order to reduce the footprint of the device, thereby increasing the density of the device. However, how to further reduce the footprint of the device is the goal of continuous efforts at present.

### SUMMARY OF THE INVENTION

The invention provides a transistor structure and a memory structure, which can effectively reduce the footprint of the device.

The invention provides a transistor structure, which includes a first doped layer, a second doped layer, a channel layer, a gate, and a dielectric structure. The second doped layer is located on the first doped layer. The channel layer is located between the first doped layer and the second doped layer. The gate penetrates through the second doped layer and the channel layer. The second doped layer and the channel layer respectively surround the gate. The dielectric structure is located between the gate and the second doped layer and located between the gate and the channel layer.

According to an embodiment of the invention, in the transistor structure, a portion of the gate may be located in the first doped layer. The first doped layer may surround the gate.

According to an embodiment of the invention, in the transistor structure, the dielectric structure may be further located between the gate and the first doped layer.

According to an embodiment of the invention, in the transistor structure, the gate may penetrate through the first doped layer.

According to an embodiment of the invention, in the transistor structure, the dielectric structure may cover one end of the gate located in the first doped layer.

According to an embodiment of the invention, in the transistor structure, the first doped layer, the second doped layer, and the channel layer may be derived from the same material layer.

According to an embodiment of the invention, in the transistor structure, the first doped layer, the second doped layer, and the channel layer may be derived from different material layers.

According to an embodiment of the invention, the transistor structure may further include an insulating layer. The insulating layer surrounds the first doped layer, the second doped layer, and the channel layer.

The invention provides a memory structure, which includes a transistor structure and a storage node. The transistor structure includes a first doped layer, a second doped layer, a channel layer, a gate, and a dielectric structure. The second doped layer is located on the first doped layer. The channel layer is located between the first doped layer and the second doped layer. The gate penetrates through the second doped layer and the channel layer. The second doped layer and the channel layer respectively surround the gate. The dielectric structure is located between the gate and the second doped layer and located between the gate and the channel layer. The storage node is electrically connected to one of the first doped layer and the second doped layer.

According to an embodiment of the invention, in the memory structure, a portion of the gate may be located in the first doped layer. The first doped layer may surround the gate.

According to an embodiment of the invention, in the memory structure, the dielectric structure may be further located between the gate and the first doped layer.

According to an embodiment of the invention, in the memory structure, the gate may penetrate through the first doped layer.

According to an embodiment of the invention, in the memory structure, the dielectric structure may cover one end of the gate located in the first doped layer.

According to an embodiment of the invention, the memory structure may further include an insulating layer. The insulating layer surrounds the first doped layer, the channel layer, and the second doped layer.

According to an embodiment of the invention, the memory structure may be a dynamic random access memory (DRAM).

According to an embodiment of the invention, in the memory structure, the storage node may be a capacitor.

According to an embodiment of the invention, the memory structure may further include a first conductive line, a second conductive line, a conductive plug, and a third conductive line. The first conductive line is electrically connected to the gate. The second conductive line is electrically connected to the second doped layer. The conductive plug is electrically connected to the second conductive line and the storage node. The storage node and the first conductive line may be located on the same side of the transistor structure. The third conductive line is electrically connected to the first doped layer.

According to an embodiment of the invention, the memory structure may further include a first conductive line, a second conductive line, and a conductive plug. The first conductive line is electrically connected to the gate. The second conductive line is electrically connected to the second doped layer. The conductive plug is electrically connected to the first doped layer and the storage node. The storage node and the first conductive line may be respectively located on opposite sides of the transistor structure.

According to an embodiment of the invention, in the memory structure, the transistor structure and the storage node may be located on the same substrate.

According to an embodiment of the invention, in the memory structure, the transistor structure and the storage node may be located on different substrates.

Based on the above description, in the transistor structure and memory structure according to the invention, the channel layer is located between the first doped layer and the second doped layer, the gate penetrates through the second doped layer and the channel layer, and the second doped layer and the channel layer respectively surround the gate. In addition, the dielectric structure is located between the gate and the second doped layer and located between the gate and the channel layer. Thereby, the transistor structure can be a channel-all-around (CAA) transistor and can effectively reduce the footprint of the device to increase the density of the device.

In order to make the aforementioned and other objects, features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a perspective view illustrating a transistor structure according to an embodiment of the invention.

FIG. 1B is a cross-sectional view taken along section line I-I′ in FIG. 1A.

FIG. 1C is a perspective view illustrating a transistor structure according to an embodiment of the invention.

FIG. 1D is a perspective view illustrating a transistor array according to an embodiment of the invention.

FIG. 2A is a perspective view illustrating a transistor structure according to another embodiment of the invention.

FIG. 2B is a cross-sectional view taken along section line II-II′ in FIG. 2A.

FIG. 2C is a perspective view illustrating a transistor structure according to another embodiment of the invention.

FIG. 3A is a perspective view illustrating a transistor structure according to another embodiment of the invention.

FIG. 3B is a cross-sectional view taken along section line III-III′ in FIG. 3A.

FIG. 3C is a perspective view illustrating a transistor structure according to another embodiment of the invention.

FIG. 4A is a perspective view illustrating a transistor structure according to another embodiment of the invention.

FIG. 4B is a cross-sectional view taken along section line IV-IV′ in FIG. 4A.

FIG. 4C is a perspective view illustrating a transistor structure according to another embodiment of the invention.

FIG. 5 is a perspective view illustrating a memory structure according to an embodiment of the invention.

FIG. 6 is a perspective view illustrating a memory structure according to another embodiment of the invention.

### DESCRIPTION OF THE EMBODIMENTS

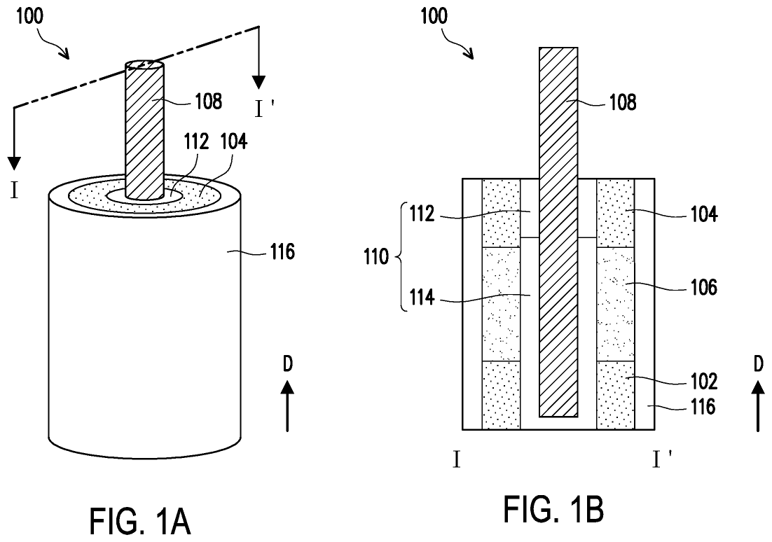

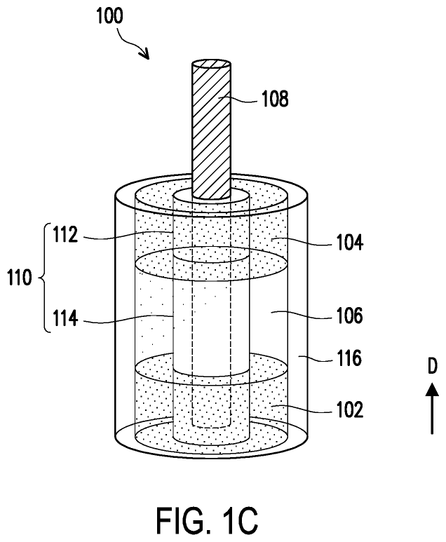

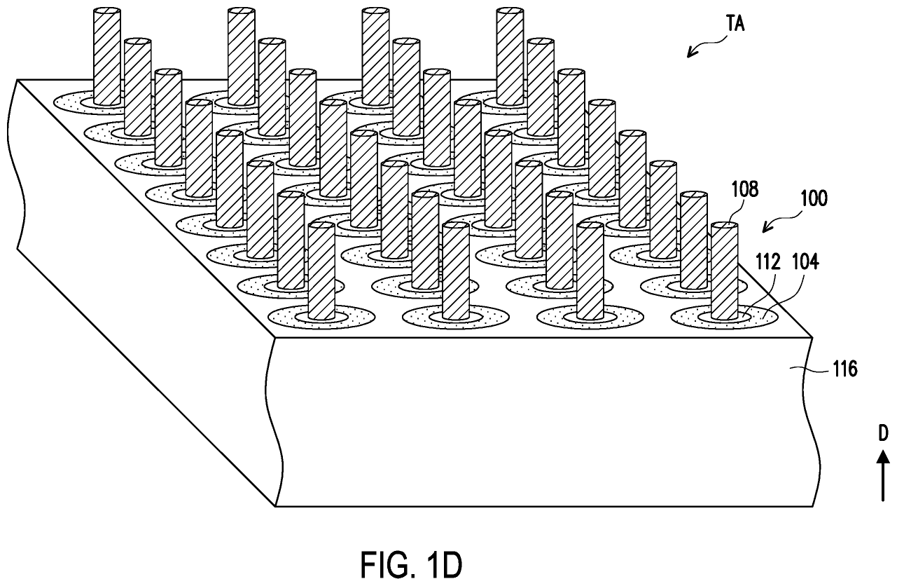

FIG. 1A is a perspective view illustrating a transistor structure according to an embodiment of the invention. FIG. 1B is a cross-sectional view taken along section line I-I′ in FIG. 1A. FIG. 1C is a perspective view illustrating a transistor structure according to an embodiment of the invention. In addition, in FIG. 1C, the doped layer 102, the doped layer 104, the channel layer 106, and the insulating layer 116 are presented in a transparent manner. FIG. 1D is a perspective view illustrating a transistor array according to an embodiment of the invention.

Referring to FIG. 1A to FIG. 1C, a transistor structure 100 includes a doped layer 102, a doped layer 104, a channel layer 106, a gate 108, and a dielectric structure 110. The transistor structure 100 may be located on a substrate. In the present embodiment and other embodiments, in order to simplify the drawings, the substrate is not shown. The substrate may be a semiconductor substrate such as a silicon substrate. The doped layer 102 may be used as the source or the drain of the transistor. The doped layer 102 may be a doped semiconductor layer. In some embodiments, the aforementioned semiconductor layer may be a portion of the substrate. In other embodiments, the aforementioned semiconductor layer may be a semiconductor layer other than the substrate. For example, the material of the aforementioned semiconductor layer may be a Group IV semiconductor material (e.g., silicon (Si), germanium (Ge), silicon germanium alloy (SiGe), or silicon carbide (SiC)), a Group III-V semiconductor material (e.g., gallium arsenide (GaAs), gallium nitride (GaN), or indium phosphide (InP)), or a Group II-VI semiconductor material (e.g., zinc selenide (ZnSe)).

The doped layer 104 is located on the doped layer 102. The doped layer 104 may be used as the source or the drain of the transistor. The doped layer 104 may be a doped semiconductor layer. In some embodiments, the aforementioned semiconductor layer may be a portion of the substrate. In other embodiments, the aforementioned semiconductor layer may be a semiconductor layer other than the substrate. For example, the material of the aforementioned semiconductor layer may be a Group IV semiconductor material (e.g., Si, Ge, SiGe, or SiC), a Group III-V semiconductor material (e.g., GaAs, GaN, or InP), or a Group II-VI semiconductor material (e.g., ZnSe).

The channel layer 106 is located between the doped layer 102 and the doped layer 104. In some embodiments, the channel layer 106 may be directly connected to the doped layer 102 and the doped layer 104. The channel layer 106 may be used as the channel of the transistor. The channel layer 106 may be a semiconductor layer. In some embodiments, the aforementioned semiconductor layer may be a portion of the substrate. In other embodiments, the aforementioned semiconductor layer may be a semiconductor layer other than the substrate. For example, the material of the aforementioned semiconductor layer may be a Group IV semiconductor material (e.g., Si, Ge, SiGe, or SiC), a Group III-V semiconductor material (e.g., GaAs, GaN, or InP), or a Group II-VI semiconductor material (e.g., ZnSe).

In some embodiments, the doped layer 102, the doped layer 104, and the channel layer 106 may be derived from the same material layer (e.g., semiconductor layer), but the invention is not limited thereto. In other embodiments, the doped layer 102, the doped layer 104, and the channel layer 106 may be derived from different material layers (e.g., semiconductor layers). In addition, the doping types of the doped layer 102, the doped layer 104, and the channel layer 106 may be set and adjusted according to the product requirement.

The gate 108 penetrates through the doped layer 104 and the channel layer 106. The doped layer 104 and the channel layer 106 respectively surround the gate 108. In some embodiments, a portion of the gate 108 may be located in the doped layer 102, but the gate 108 does not penetrate through the doped layer 102. The doped layer 102 may surround the gate 108. In the present embodiment, the gate 108 may protrude from the top surface of the doped layer 104, but the invention is not limited thereto. The material of the gate 108 may be a semiconductor material, a metal, or a metal compound. The semiconductor material is, for example, doped polysilicon. The metal is, for example, aluminum or tungsten. The metal compound is, for example, titanium nitride (TiN).

The dielectric structure 110 is located between the gate 108 and the doped layer 104, so that the gate 108 and the doped layer 104 can be electrically insulated from each other. In addition, the dielectric structure 110 is located between the gate 108 and the channel layer 106, so that the gate 108 and the channel layer 106 can be electrically insulated from each other. In some embodiments, the dielectric structure 110 may be further located between the gate 108 and the doped layer 102, so that the gate 108 and the doped layer 102 can be electrically insulated from each other. In some embodiments, the dielectric structure 110 may cover one end of the gate 108 located in the doped layer 102. The material of the dielectric structure 110 is, for example, silicon oxide, hafnium oxide, or a combination thereof.

The dielectric structure 110 may be a single-layer structure or a multilayer structure. In the present embodiment, the dielectric structure 110 is, for example, a multilayer structure, but the invention is not limited thereto. For example, the dielectric structure 110 may include a dielectric layer 112 and a dielectric layer 114. The dielectric layer 112 is located between the gate 108 and the doped layer 104. In some embodiments, the dielectric layer 112 may be a spacer. The dielectric layer 114 is located between the gate 108 and the channel layer 106, and the dielectric layer 114 can be used as a gate dielectric layer. In some embodiments, the dielectric layer 114 may be further located between the gate 108 and the doped layer 102 and may cover one end of the gate 108 located in the doped layer 102. The materials of the dielectric layer 112 and the dielectric layer 114 are, for example, silicon oxide or hafnium oxide.

Furthermore, the transistor structure 100 may further include an insulating layer 116. The insulating layer 116 surrounds the doped layer 102, the doped layer 104, and the channel layer 106. The insulating layer 116 can be used to isolate the transistor structure 100 from other devices. For example, as shown in FIG. 1D, in the transistor array TA, the adjacent transistor structures 100 can be isolated from each other by the insulating layer 116. In some embodiments, the insulating layers 116 of the adjacent transistor structures 100 may be connected to each other to form a single layer. The insulating layer 116 may be a single-layer structure or a multilayer structure. The material of the insulating layer 116 is, for example, silicon oxide, a low dielectric constant (low-k) material, an air gap, or a combination thereof.

In some embodiments, the extension direction D of the gate 108 of the transistor structure 100 may be perpendicular to the top surface of the substrate to become a vertical transistor device, but the invention is not limited thereto. In other embodiments, the extension direction D of the gate 108 of the transistor structure 100 may be parallel to the top surface of the substrate to become a horizontal transistor device.

On the other hand, the transistor structure 100 may be a full depletion type transistor device or a partial depletion type transistor device. When the transistor structure 100 is the partial depletion type transistor device, a body line (not shown) may be used to eliminate the floating body effect.

Based on the above embodiment, in the transistor structure 100, the channel layer 106 is located between the doped layer 102 and the doped layer 104, the gate 108 penetrates through the doped layer 104 and the channel layer 106, and the doped layer 104 and the channel layer 106 respectively surround the gate 108. In addition, the dielectric structure 110 is located between the gate 108 and the doped layer 104 and located between the gate 108 and the channel layer 106. Thereby, the transistor structure 100 can be a channel-all-around (CAA) transistor and can effectively reduce the footprint of the transistor device to increase the density of the device. Furthermore, when the transistor structure 100 includes the insulating layer 116, the transistor structure 100 may be a CAA-on-insulator transistor (CAAOI transistor). Moreover, since the channel layer 106 of the transistor structure 100 is covered by the insulator (e.g., the dielectric structure 110 and the insulating layer 116), the formation of leakage path can be effectively prevented.

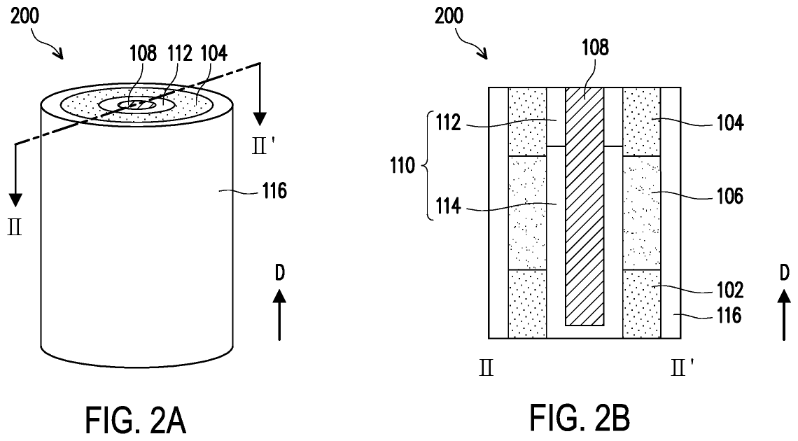

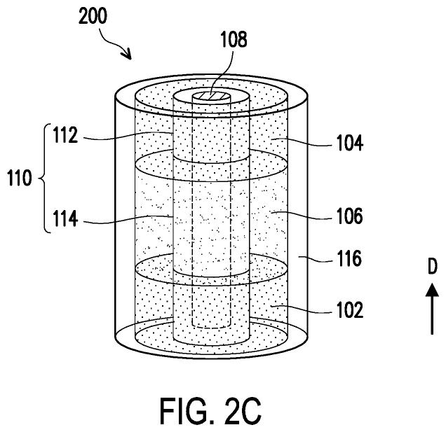

FIG. 2A is a perspective view illustrating a transistor structure according to another embodiment of the invention. FIG. 2B is a cross-sectional view taken along section line II-II′ in FIG. 2A. FIG. 2C is a perspective view illustrating a transistor structure according to another embodiment of the invention. In addition, in FIG. 2C, the doped layer 102, the doped layer 104, the channel layer 106, and the insulating layer 116 are presented in a transparent manner.

Referring to FIG. 1A to FIG. 1C and FIG. 2A to FIG. 2C, the difference between the transistor structure 200 of FIG. 2A to FIG. 2C and the transistor structure 100 of FIG. 1A to FIG. 1C is as follows. In the transistor structure 200, the gate 108 may not protrude from the top surface of the doped layer 104. In addition, the same or similar components in FIG. 2A to FIG. 2C and FIG. 1A to FIG. 1C are denoted by the same symbols, and the description thereof is omitted.

Based on the above embodiment, in the transistor structure 200, the channel layer 106 is located between the doped layer 102 and the doped layer 104, the gate 108 penetrates through the doped layer 104 and the channel layer 106, and the doped layer 104 and the channel layer 106 respectively surround the gate 108. In addition, the dielectric structure 110 is located between the gate 108 and the doped layer 104 and located between the gate 108 and the channel layer 106. Thereby, the transistor structure 200 can be a CAA transistor and can effectively reduce the footprint of the transistor device to increase the density of the device. Furthermore, when the transistor structure 200 includes the insulating layer 116, the transistor structure 200 can be a CAAOI transistor. Moreover, since the channel layer 106 of the transistor structure 200 is covered by the insulator (e.g., the dielectric structure 110 and the insulating layer 116), the formation of leakage path can be effectively prevented.

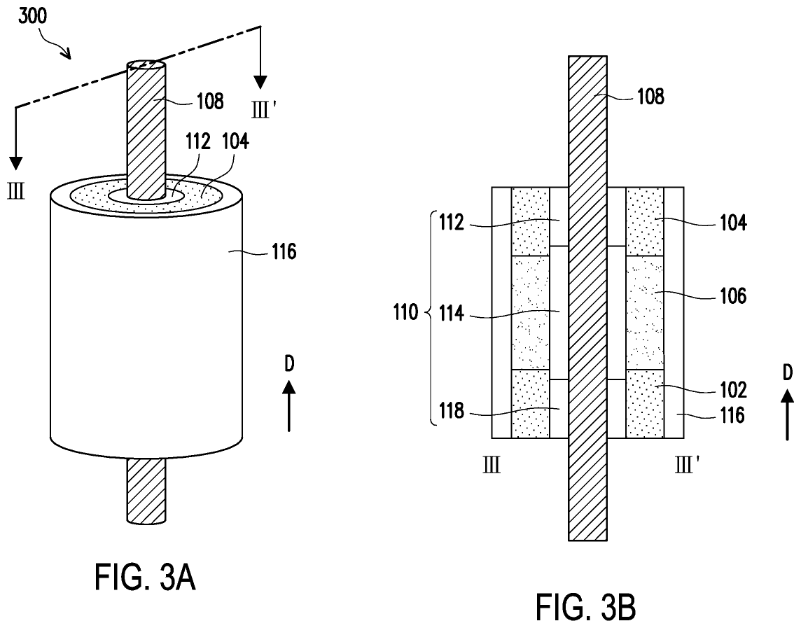

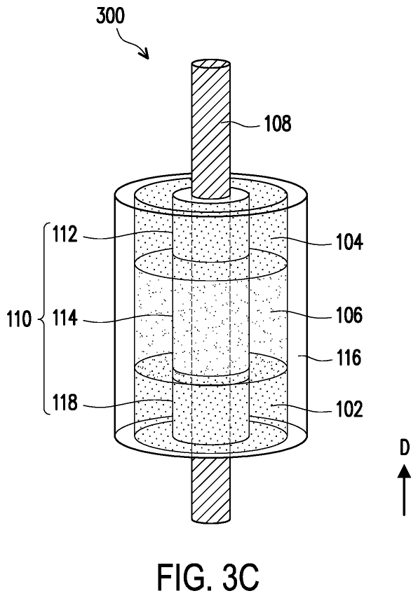

FIG. 3A is a perspective view illustrating a transistor structure according to another embodiment of the invention. FIG. 3B is a cross-sectional view taken along section line III-III′ in FIG. 3A. FIG. 3C is a perspective view illustrating a transistor structure according to another embodiment of the invention. In addition, in FIG. 3C, the doped layer 102, the doped layer 104, the channel layer 106, and the insulating layer 116 are presented in a transparent manner.

Referring to FIG. 1A to FIG. 1C and FIG. 3A to FIG. 3C, the difference between the transistor structure 300 of FIG. 3A to FIG. 3C and the transistor structure 100 of FIG. 1A to FIG. 1C is as follows. In the transistor structure 300, the gate 108 may penetrate through the doped layer 102. The doped layer 102 may surround the gate 108. In the present embodiment, the gate 108 may further protrude from the bottom surface of the doped layer 102, but the invention is not limited thereto. In addition, in the transistor structure 300, the dielectric structure 110 may further include a dielectric layer 118. The dielectric layer 118 may be located between the gate 108 and the doped layer 102. In some embodiments, the dielectric layer 118 may be a spacer. The material of the dielectric layer 118 is, for example, silicon oxide or hafnium oxide. In the present embodiment, the dielectric structure 110 is, for example, a multilayer structure, but the invention is not limited thereto. In other embodiments, the dielectric structure 110 may be a single-layer structure. Furthermore, the same or similar components in FIG. 3A to FIG. 3C and FIG. 1A to FIG. 1C are denoted by the same symbols, and the description thereof is omitted.

Based on the above embodiment, in the transistor structure 300, the channel layer 106 is located between the doped layer 102 and the doped layer 104, the gate 108 penetrates through the doped layer 104 and the channel layer 106, and the doped layer 104 and the channel layer 106 respectively surround the gate 108. In addition, the dielectric structure 110 is located between the gate 108 and the doped layer 104 and located between the gate 108 and the channel layer 106. Thereby, the transistor structure 300 can be a CAA transistor and can effectively reduce the footprint of the transistor device to increase the density of the device. Furthermore, when the transistor structure 300 includes the insulating layer 116, the transistor structure 300 can be a CAAOI transistor. Moreover, since the channel layer 106 of the transistor structure 300 is covered by the insulator (e.g., the dielectric structure 110 and the insulating layer 116), the formation of leakage path can be effectively prevented.

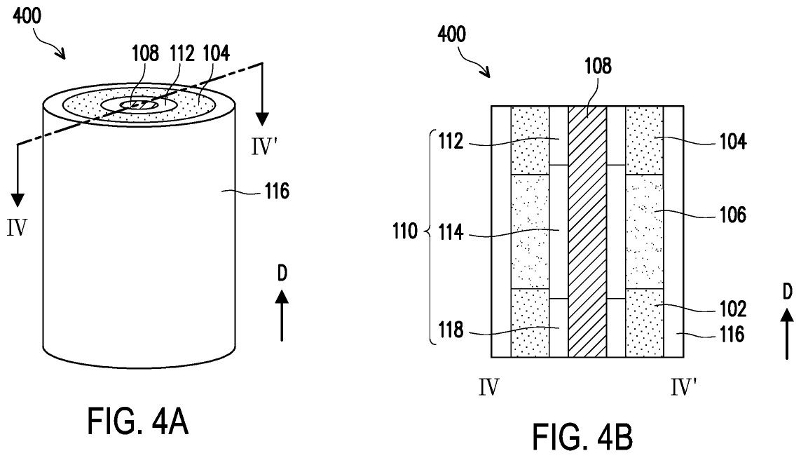

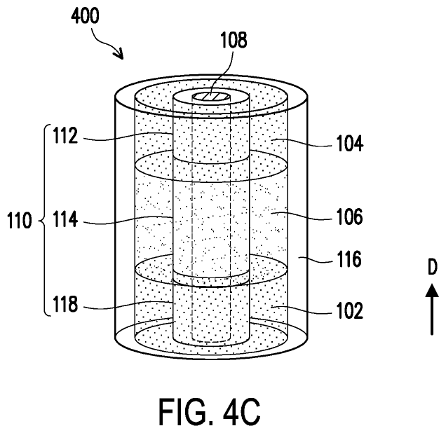

FIG. 4A is a perspective view illustrating a transistor structure according to another embodiment of the invention. FIG. 4B is a cross-sectional view taken along section line IV-IV′ in FIG. 4A. FIG. 4C is a perspective view illustrating a transistor structure according to another embodiment of the invention. In addition, in FIG. 4C, the doped layer 102, the doped layer 104, the channel layer 106, and the insulating layer 116 are presented in a transparent manner.

Referring to FIG. 3A to FIG. 3C and FIG. 4A to FIG. 4C, the difference between the transistor structure 400 of FIG. 4A to FIG. 4C and the transistor structure 300 of FIG. 3A to FIG. 3C is as follows. In the transistor structure 400, the gate 108 may not protrude from the top surface of the doped layer 104. In some embodiments, the gate 108 may not protrude from the bottom surface of the doped layer 102. In addition, the same or similar components in FIG. 4A to FIG. 4C and FIG. 3A to FIG. 3C are denoted by the same symbols, and the description thereof is omitted.

Based on the above embodiment, in the transistor structure 400, the channel layer 106 is located between the doped layer 102 and the doped layer 104, the gate 108 penetrates through the doped layer 104 and the channel layer 106, and the doped layer 104 and the channel layer 106 respectively surround the gate 108. In addition, the dielectric structure 110 is located between the gate 108 and the doped layer 104 and located between the gate 108 and the channel layer 106. Thereby, the transistor structure 400 can be a CAA transistor and can effectively reduce the footprint of the transistor device to increase the density of the device. Furthermore, when the transistor structure 400 includes the insulating layer 116, the transistor structure 400 can be a CAAOI transistor. Moreover, since the channel layer 106 of the transistor structure 400 is covered by the insulator (e.g., the dielectric structure 110 and the insulating layer 116), the formation of leakage path can be effectively prevented.

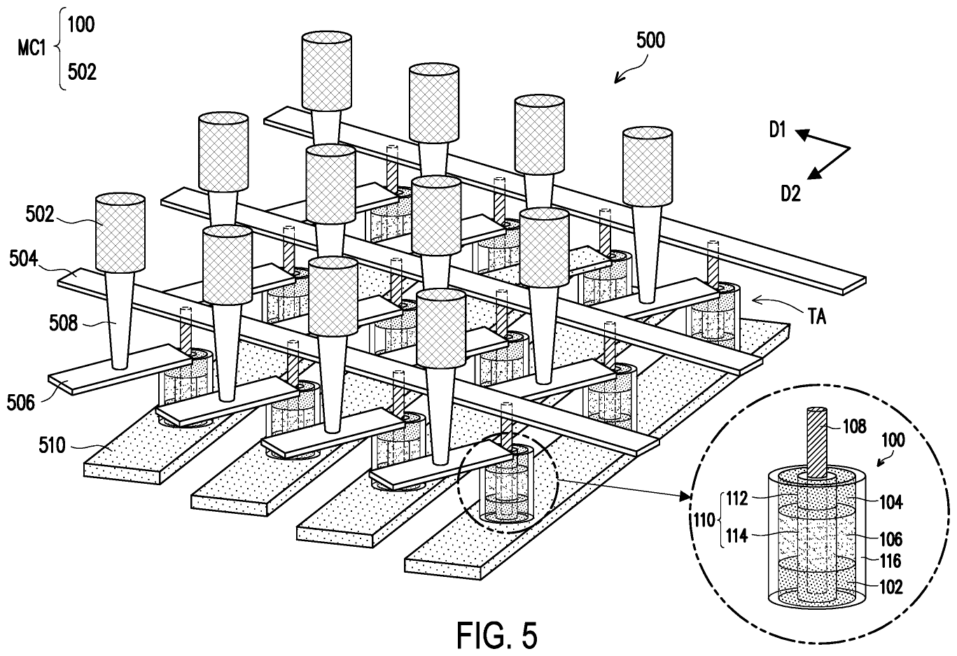

FIG. 5 is a perspective view illustrating a memory structure according to an embodiment of the invention. In addition, in order to clearly describe the arrangement relationship between the components, the transistor structure 100 in FIG. 5 is shown in a partially transparent manner. Furthermore, in the transistor array TA of FIG. 5, the insulating layers 116 of the adjacent transistor structures 100 may be connected to each other to form a single layer (as shown in FIG. 1D). However, in order to clearly describe the relationship between the components, only a portion of the insulating layer 116 is shown in FIG. 5.

Referring to FIG. 5, the memory structure 500 includes a transistor structure 100 and a storage node 502. In addition, the storage node 502 and the transistor structure 100 electrically connected to each other may form a memory cell MC1. In the present embodiment, the memory structure 500 may be a dynamic random access memory (DRAM), but the invention is not limited thereto. Furthermore, the detailed content of the transistor structure 100 may be referred to the description of the above-mentioned embodiment, and the description thereof is omitted here.

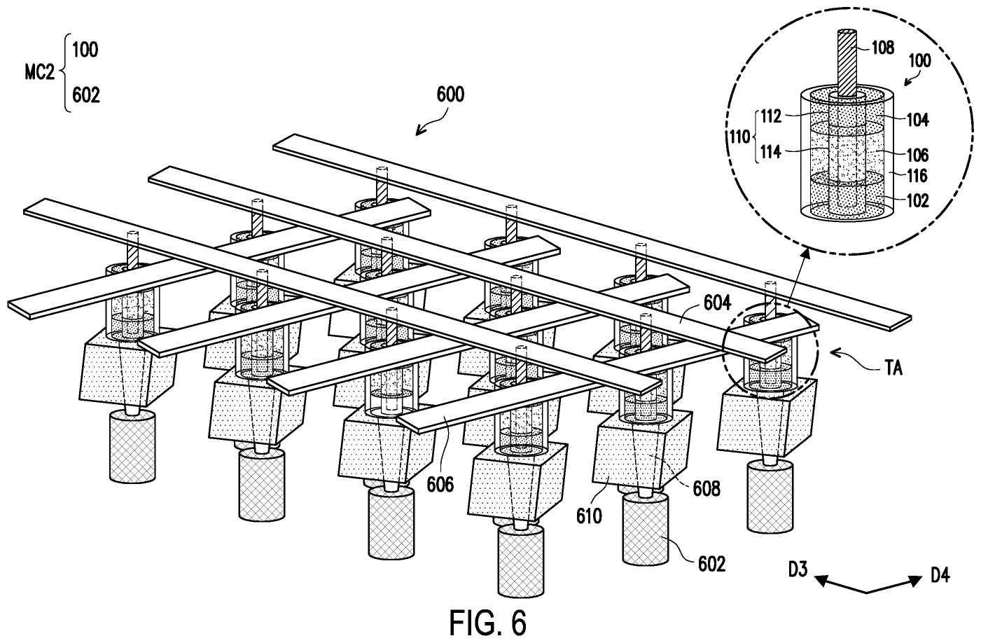

The storage node 502 is electrically connected to one of the doped layer 102 and the doped layer 104 of the transistor structure 100. In the present embodiment, the storage node 502 is, for example, electrically connected to the doped layer 104, but the invention is not limited thereto. In other embodiments, the storage node 502 may be electrically connected to the doped layer 102 (FIG. 6). In the present embodiment, when the memory structure 500 is a DRAM, the storage node 502 may be a capacitor. In addition, the capacitor used as the storage node 502 may be any capacitor suitable for the DRAM, and the description thereof is omitted here.

In some embodiments, the transistor structure 100 and the storage node 502 may be located on the same substrate (e.g., semiconductor substrate). In other embodiments, the transistor structure 100 and the storage node 502 may be located on different substrates. For example, the transistor structure 100 may be located on one substrate (e.g., semiconductor substrate), and the storage node 502 may be located on another substrate (e.g., interposer).

In addition, the memory structure 500 may further include a conductive line 504, a conductive line 506, a conductive plug 508, and a conductive line 510. In the present embodiment, the storage node 502 and the conductive line 504 may be located on the same side of the transistor structure 100, but the invention is not limited thereto. The conductive line 504 is electrically connected to the gate 108 of the transistor structure 100. In some embodiments, the conductive line 504 may be directly connected to the gate 108, but the invention is not limited thereto. Furthermore, the gates 108 in the transistor structures 100 arranged in the extension direction D1 of the conductive line 504 may be electrically connected to the same conductive line 504. That is, the memory cells MC1 arranged in the extension direction D1 of the conductive line 504 may share the conductive line 504. The conductive line 504 may be used as a word line. The material of the conductive line 504 is, for example, metal such as aluminum or copper.

The conductive line 506 is electrically connected to the doped layer 104. In some embodiments, the conductive line 506 may be directly connected to the doped layer 104, but the invention is not limited thereto. In addition, as long as the conductive line 506 may be electrically connected to the doped layer 104, the shape of the conductive line 506 may be adjusted according to the product requirement and is not limited to the shape in FIG. 5. The material of the conductive line 506 is, for example, metal such as aluminum or copper.

The conductive plug 508 is electrically connected to the conductive line 506 and the storage node 502 and is located between the conductive line 506 and the storage node 502. In this way, the storage node 502 may be electrically connected to the doped layer 104 of the transistor structure 100 by the conductive plug 508 and the conductive line 506. In some embodiments, the conductive plug 508 may be directly connected to the conductive line 506 and the storage node 502, but the invention is not limited thereto. In some embodiments, the conductive plug 508 is, for example, a via.

The conductive line 510 is electrically connected to the doped layer 102. The conductive line 510 may be used as a bit line. In some embodiments, the conductive line 510 may be directly connected to the doped layer 102, but the invention is not limited thereto. In addition, the doped layers 102 in the transistor structures 100 arranged in the extension direction D2 of the conductive line 510 may be electrically connected to the same conductive line 510. That is, the memory cells MC1 arranged in the extension direction D2 of the conductive line 510 may share the conductive line 510. The material of the conductive line 510 may be a doped semiconductor layer, metal, or a metal compound. In some embodiments, the aforementioned semiconductor layer may be a portion of the substrate. In other embodiments, the aforementioned semiconductor layer may be a semiconductor layer other than the substrate. The material of the aforementioned semiconductor layer may be a Group IV semiconductor material (e.g., Si, Ge, SiGe, or SiC), a Group III-V semiconductor material (e.g., GaAs, GaN, or InP), or a Group II-VI semiconductor material (e.g., ZnSe). The metal is, for example, aluminum or tungsten. The metal compound is, for example, titanium nitride.

In the present embodiment, the transistor structure in the memory structure 500 is, for example, the transistor structure 100 in FIG. 1C, but the invention is not limited thereto. In other embodiments, the transistor structure in the memory structure 500 may be the transistor structure 200 in FIG. 2C, the transistor structure 300 in FIG. 3C, or the transistor structure 400 in FIG. 4C, and the connection manner of the interconnect structure may be adjusted accordingly. For example, when the transistor structure in the memory structure 500 is the transistor structure 200 in FIG. 2C or the transistor structure 400 in FIG. 4C, since the gate 108 does not protrude from the top surface of the doped layer 104, the conductive line 504 may be electrically connected to the gate 108 by a conductive plug (e.g., contact).

Furthermore, the memory structure 500 may further include other required dielectric layers (for isolation) and/or other required interconnect structures (for electrical connection), and the description thereof is omitted here.

Based on the above embodiment, in the memory structure 500, since the transistor structure 100 has a smaller footprint, the footprint of the memory device can be effectively reduced to increase the density of the device. In addition, when the transistor structure 100 in the memory structure 500 is a CAAOI transistor, the formation of leakage path can be effectively prevented.

FIG. 6 is a perspective view illustrating a memory structure according to another embodiment of the invention. In addition, in order to clearly describe the arrangement relationship between the components, the transistor structure 100 in FIG. 6 is shown in a partially transparent manner. Furthermore, in the transistor array TA of FIG. 6, the insulating layers 116 of the adjacent transistor structures 100 may be connected to each other to form a single layer (as shown in FIG. 1D). However, in order to clearly describe the relationship between the components, only a portion of the insulating layer 116 is shown in FIG. 6.

Referring to FIG. 6, the memory structure 600 includes a transistor structure 100 and a storage node 602. In addition, the storage node 602 and the transistor structure 100 electrically connected to each other may form a memory cell MC2. In the present embodiment, the memory structure 600 may be a DRAM, but the invention is not limited thereto. Furthermore, the detailed content of the transistor structure 100 may be referred to the description of the above-mentioned embodiment, and the description thereof is omitted here.

The storage node 602 is electrically connected to one of the doped layer 102 and the doped layer 104 of the transistor structure 100. In the present embodiment, the storage node 602 is, for example, electrically connected to the doped layer 102, but the invention is not limited thereto. In the present embodiment, when the memory structure 600 is a DRAM, the storage node 602 may be a capacitor. In addition, the capacitor used as the storage node 602 may be any capacitor suitable for the DRAM, and the description thereof is omitted here.

In some embodiments, the transistor structure 100 and the storage node 602 may be located on the same substrate (e.g., semiconductor substrate). In other embodiments, the transistor structure 100 and the storage node 602 may be located on different substrates. For example, the transistor structure 100 may be located on one substrate (e.g., semiconductor substrate), and the storage node 602 may be located on another substrate (e.g., interposer).

In addition, the memory structure 600 may further include a conductive line 604, a conductive line 606, and a conductive plug 608. In the present embodiment, the storage node 602 and the conductive line 604 may be respectively located on opposite sides of the transistor structure 100, but the invention is not limited thereto. The conductive line 604 is electrically connected to the gate 108 of the transistor structure 100. In some embodiments, the conductive line 604 may be directly connected to the gate 108, but the invention is not limited thereto. Furthermore, the gates 108 in the transistor structures 100 arranged in the extension direction D3 of the conductive line 604 may be electrically connected to the same conductive line 604. That is, the memory cells MC2 arranged in the extension direction D3 of the conductive line 604 may share the conductive line 604. The conductive line 604 may be used as a word line. The material of the conductive line 604 is, for example, metal such as aluminum or copper.

The conductive line 606 is electrically connected to the doped layer 104. The conductive line 606 may be used as a bit line. In some embodiments, the conductive line 606 may be directly connected to the doped layer 104, but the invention is not limited thereto. In addition, the doped layers 104 in the transistor structures 100 arranged in the extension direction D4 of the conductive line 606 may be electrically connected to the same conductive line 606. That is, the memory cells MC2 arranged in the extension direction D4 of the conductive line 606 may share the conductive line 606. Furthermore, as long as the conductive line 606 may be electrically connected to the doped layer 104, the shape of the conductive line 606 may be adjusted according to the product requirement and is not limited to the shape in FIG. 6. The material of the conductive line 606 is, for example, metal such as aluminum or copper.

The conductive plug 608 is electrically connected to the doped layer 102 and the storage node 602 and is located between the doped layer 102 and the storage node 602, so that the storage node 602 may be electrically connected to the doped layer 102 of the transistor structure 100. In some embodiments, the conductive plug 608 may be directly connected to the doped layer 102 and the storage node 602, but the invention is not limited thereto. In some embodiments, the conductive plug 608 is, for example, a via.

In some embodiments, the memory structure 600 may further include a doped extension portion 610. The doped extension portion 610 is electrically connected to the doped layer 102, so that the doped extension portion 610 may serve as an extension portion of the doped layer 102. In some embodiments, the doped extension portion 610 may be directly connected to the doped layer 102. In addition, the conductive plug 608 may penetrate through the doped extension portion 610. The doped extension portion 610 may be a doped semiconductor layer, but the invention is not limited thereto. In some embodiments, the aforementioned semiconductor layer may be a portion of the substrate. In other embodiments, the aforementioned semiconductor layer may be a semiconductor layer other than the substrate. For example, the material of the aforementioned semiconductor layer may be a Group IV semiconductor material (e.g., Si, Ge, SiGe, or SiC), a Group III-V semiconductor material (e.g., GaAs, GaN, or InP), or a Group II-VI semiconductor material (e.g., ZnSe).

In the present embodiment, the transistor structure in the memory structure 600 is, for example, the transistor structure 100 in FIG. 1C, but the invention is not limited thereto. In other embodiments, the transistor structure in the memory structure 600 may be the transistor structure 200 in FIG. 2C, the transistor structure 300 in FIG. 3C, or the transistor structure 400 in FIG. 4C, and the connection manner of the interconnect structure may be adjusted accordingly. For example, when the transistor structure in the memory structure 600 is the transistor structure 200 in FIG. 2C or the transistor structure 400 in FIG. 4C, since the gate 108 does not protrude from the top surface of the doped layer 104, the conductive line 604 may be electrically connected to the gate 108 by a conductive plug (e.g., contact).

Furthermore, the memory structure 600 may further include other required dielectric layers (for isolation) and/or other required interconnect structures (for electrical connection), and the description thereof is omitted here.

Based on the above embodiment, in the memory structure 600, since the transistor structure 100 has a smaller footprint, the footprint of the memory device can be effectively reduced to increase the density of the device. In addition, when the transistor structure 100 in the memory structure 600 is a CAAOI transistor, the formation of leakage path can be effectively prevented.

In summary, in the transistor structure and the memory structure of the aforementioned embodiments, the channel layer is located between the first doped layer and the second doped layer, the gate penetrates through the second doped layer and the channel layer, and the second doped layer and the channel layer respectively surround the gate. In addition, the dielectric structure is located between the gate and the second doped layer and located between the gate and the channel layer. Thereby, the transistor structure can be a CAA transistor and can effectively reduce the footprint of the device to increase the density of the device.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A transistor structure, comprising:
a first doped layer;
a second doped layer located on the first doped layer;
a channel layer located between the first doped layer and the second doped layer;
a gate penetrating through the second doped layer and the channel layer, wherein the second doped layer and the channel layer respectively surround the gate; and
a dielectric structure located between the gate and the second doped layer and located between the gate and the channel layer.

2. The transistor structure according to claim 1, wherein a portion of the gate is located in the first doped layer, and the first doped layer surrounds the gate.

3. The transistor structure according to claim 2, wherein the dielectric structure is further located between the gate and the first doped layer.

4. The transistor structure according to claim 3, wherein the gate penetrates through the first doped layer.

5. The transistor structure according to claim 3, wherein the dielectric structure covers one end of the gate located in the first doped layer.

6. The transistor structure according to claim 1, wherein the first doped layer, the second doped layer, and the channel layer are derived from the same material layer.

7. The transistor structure according to claim 1, wherein the first doped layer, the second doped layer, and the channel layer are derived from different material layers.

8. The transistor structure according to claim 1, further comprising:
an insulating layer surrounding the first doped layer, the second doped layer, and the channel layer.

9. A memory structure, comprising:
a transistor structure comprising:
a first doped layer;
a second doped layer located on the first doped layer;
a channel layer located between the first doped layer and the second doped layer;
a gate penetrating through the second doped layer and the channel layer, wherein the second doped layer and the channel layer respectively surround the gate; and
a dielectric structure located between the gate and the second doped layer and located between the gate and the channel layer; and
a storage node electrically connected to one of the first doped layer and the second doped layer.

10. The memory structure according to claim 9, wherein a portion of the gate is located in the first doped layer, and the first doped layer surrounds the gate.

11. The memory structure according to claim 10, wherein the dielectric structure is further located between the gate and the first doped layer.

12. The memory structure according to claim 11, wherein the gate penetrates through the first doped layer.

13. The memory structure according to claim 11, wherein the dielectric structure covers one end of the gate located in the first doped layer.

14. The memory structure according to claim 9, further comprising:
an insulating layer surrounding the first doped layer, the channel layer, and the second doped layer.

15. The memory structure according to claim 9, wherein the memory structure comprises a dynamic random access memory.

16. The memory structure according to claim 15, wherein the storage node comprises a capacitor.

17. The memory structure according to claim 9, further comprising:
a first conductive line electrically connected to the gate;
a second conductive line electrically connected to the second doped layer;
a conductive plug electrically connected to the second conductive line and the storage node, wherein the storage node and the first conductive line are located on the same side of the transistor structure; and
a third conductive line electrically connected to the first doped layer.

18. The memory structure according to claim 9, further comprising:
a first conductive line electrically connected to the gate;
a second conductive line electrically connected to the second doped layer; and
a conductive plug electrically connected to the first doped layer and the storage node, wherein the storage node and the first conductive line are respectively located on opposite sides of the transistor structure.

19. The memory structure according to claim 9, wherein the transistor structure and the storage node are located on the same substrate.

20. The memory structure according to claim 9, wherein the transistor structure and the storage node are located on different substrates.
